(19) United States
(12) Patent Application Publication
(10) Pub. No.: US 2006/0012954 A1
(43) Pub. Date: Jan. 19, 2006

(54) Network protector added load ability through forced convection

(76) Inventors: Arthur James Jur, Greenwood, SC (US); Douglas Michael Brandt, Greenwood, SC (US); Kevin Michael Davis, Greenwood, SC (US)

Correspondence Address: Martin J. Moran;Eaton Electrical, Inc., Technology & Quality Center, 170 Industry Drive, RIDC Park West, Pittsburgh, PA, 15275-1032, US

(21) Appl. No.: 10/894,178

(22) Filed: Jul. 19, 2004

(51) Int. Cl. H05K 7/20

(52) U.S. Cl. 361/695; 361/676

(57) ABSTRACT

A network protector that includes a housing assembly, a circuit breaker, a control assembly, and a convention cooling assembly. The housing assembly is structured to form an enclosure and has a bus assembly coupled to an interior wall. The circuit breaker is structured to engaged the bus assembly within the housing assembly. The convection cooling assembly is coupled to the housing assembly and is structured to move air over the bus assembly.

### BACKGROUND OF THE INVENTION

1. Field of the Invention

The present invention relates to network protectors and, more specifically, to a network protector having a convection cooling assembly disposed within the network protector housing.

2. Background Information

Secondary power distribution networks consist of interlaced grids which are supplied by two or more sources of power so that the loss of a single source of power will not result in an interruption of service. Such networks provide the highest level of reliability possible with conventional power distribution and are normally used to supply high-density load areas such as a section of a city, a large building, or an industrial site. Between the power sources and the network are a transformer and a network protector. Such network protectors are often found in dust-proof or moisture-proof housings which are disposed in subterranean passageways in large metropolitan areas. The housing, or “tank,” may be further disposed within a concrete vault.

The primary components of the network protector are a circuit breaker and a control compartment. The control compartment includes components, such as a relay, to sense the transformer and network voltages and line currents, and to execute algorithms to initiate breaker tripping or closing action. Trip determination is based on detecting an over current condition or reverse power flow, that is, power flow from the network to the energy source. The buses connecting the circuit breaker to the line and load are typically disposed at the back of the housing and extend upwardly towards the top on the housing. Typically, the circuit breaker is a three-phase circuit breaker wherein each phase has a bus. As electricity passes through each bus heat is created. Generally, the buses are the hottest component in the network protector.

To dissipate the heat in the buses, the buses connecting the circuit breaker to the transformer and the circuit breaker to the load typically have a hollow square cross-section or consist of spaced laminations. These shapes increase the surface area, and therefore the thermal emissivity, of the bus. Additionally, these shapes allowed air to flow through the bus and remove heat by convection. Such heat dissipation means are generally sufficient for normal use of the circuit breaker.

Network protectors, however, are subject to their maximum current rating at peak times of service. The maximum current rating of the circuit breaker is limited by, among other factors, its maximum thermal rating. Thus, the maximum current rating of the circuit breaker could be increased if the maximum thermal rating were increased. The maximum thermal rating could be increased if the heat created in the bus assembly was dissipated at a greater rate. Moreover, if the maximum current rating of the circuit breaker could be increased, a circuit breaker that presently has a lower current rating could be used in the network protector. Generally, circuit breakers with lower current ratings are smaller and less expensive. Thus, if heat dissipation in a present network protector enclosure could be increased, the network protector could utilize a smaller and less expensive circuit breaker.

There is, therefore, a need for a network protector structured to dissipate heat.

There is a further need for a network protector convection cooling assembly structured to increase the cooling of the network protector housing buses.

There is a further need for a network protector convection cooling assembly that may be used in network protector housings currently in use.

### SUMMARY OF THE INVENTION

These needs, and others, are met by the present invention which provides a convection cooling assembly, such as a fan, structured to move air over the network protector buses. The increased fluid flow over the buses increases the amount of heat lost though convection. In the preferred embodiment, the convection cooling assembly is a directional fan, such as a propeller fan, structured to move air directly over the buses. It is also preferred that the fan be located at the bottom of the enclosure and direct airflow from the bottom of the enclosure upwardly over the buses. This allows the cooler air located at the bottom of the enclosure to move over the buses. In a more preferred embodiment, there is an individual fan for each pair of buses in the enclosure. While the fans may run continuously, the invention also provides for a control assembly that senses a characteristic of the network protector, such as, the current flowing through the circuit breaker, and activates the fans at a preset limit.

### BRIEF DESCRIPTION OF THE DRAWINGS

A full understanding of the invention can be gained from the following description of the preferred embodiments when read in conjunction with the accompanying drawings in which:

FIG. 1 is a front view of a network protector having a convection cooling assembly.

FIG. 2 is a side view of a network protector having a convection cooling assembly.

FIG. 3 is a side view of an alternate embodiment of a network protector having a convection cooling assembly.

### DESCRIPTION OF THE PREFERRED EMBODIMENTS

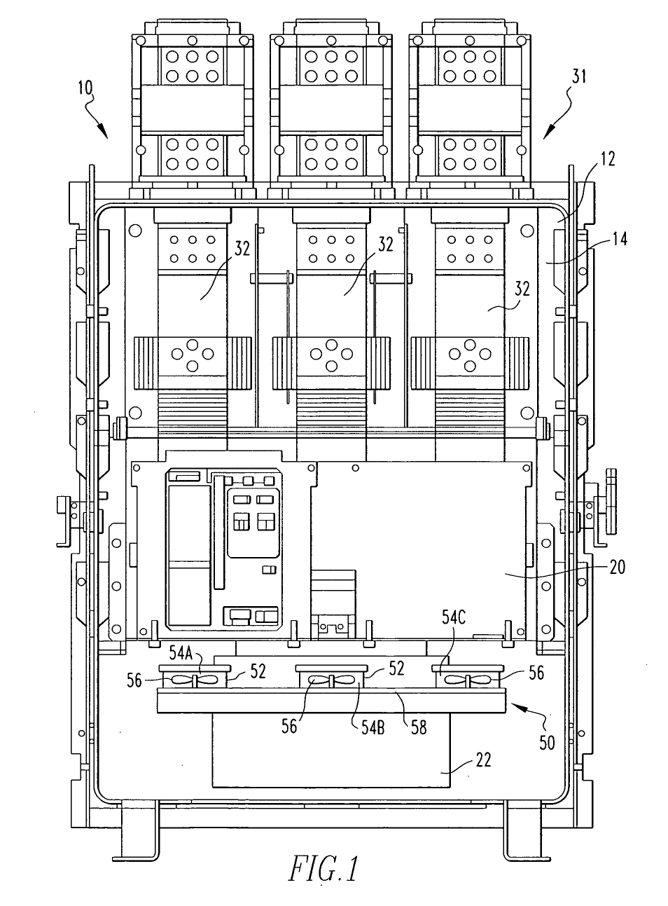

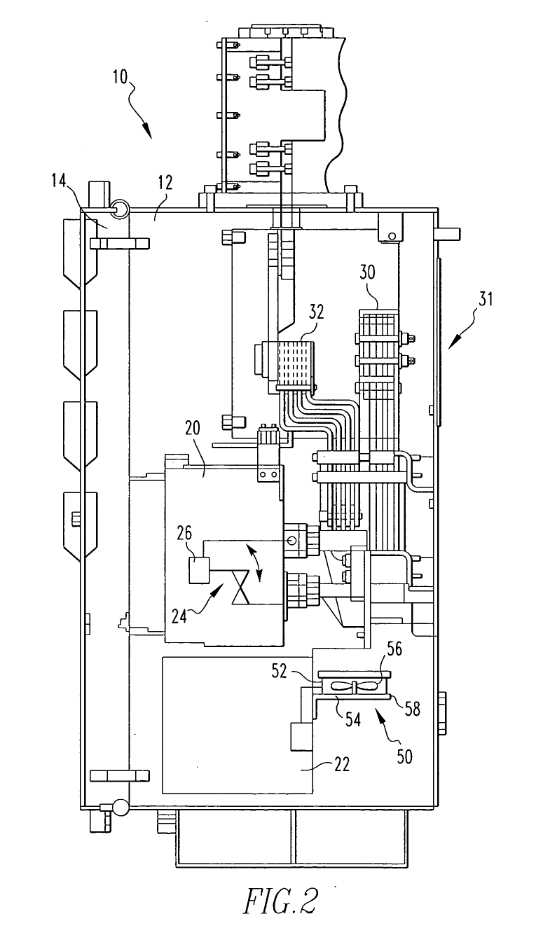

As shown in FIGS. 1 and 2, a network protector 10 includes a housing assembly 12 structured to form an enclosure with a movable door 14. The housing assembly 12 is structured to be placed within a vault 16. A vault 16 is typically made of concrete or a similar material. The two primary network protector components, a circuit breaker 20 and a control assembly 22 are disposed within the housing assembly 12. The circuit breaker 20 includes at least one set of main contacts 24 (shown schematically, FIG. 2) that are structured to move between a first, open position and a second, closed position. When the main contacts 24 are in the second, closed position, electricity may flow through the circuit breaker 20. When the main contacts 24 are in the first, open position, electricity cannot flow through the circuit breaker 20. The circuit breaker 20 also includes an operating mechanism 26 (shown schematically) that is structured to move the main contacts 24 between the first and second position. The main contacts 24 are coupled to one or more network protector load buses 30 and one or more network protector line buses 32 which are part of a bus assembly 31. The bus assembly 31 is coupled to an interior wall of the housing assembly 12, preferably the back wall. In a preferred embodiment, the circuit breaker 20 is a three-phase circuit breaker having three poles. Each pole includes a pair of buses, a load bus 30 and a line bus 32. The bus assembly 31 is disposed near the back of the housing assembly 12. The circuit breaker 20 is disposed at about mid-level within the housing assembly 12 and the load buses 30 and the line buses 32 extend generally upwardly therefrom.

The network protector 10 also includes a convection cooling assembly 50. The cooling assembly 50 is structured to move air over the load buses 30 and the line buses 32 to increase to amount of heat transfer through convection. In the preferred embodiment, the convection cooling assembly 50 includes at least one fan 52 disposed adjacent to the load buses 30 and the line buses 32. The fan 52 is, preferably, a propeller fan 54 having a propeller 56 mounted on an axle (not shown). The propeller fan 54 is structured to move air in a direction generally parallel to the axis of the propeller. The propeller fan 54 is positioned to move air directly toward the load buses 30 and the line buses 32. The fan 52 may be disposed on a mounting bracket 58 that is coupled to the back side of the control assembly 22. In a more preferred embodiment, there is a propeller fan 54A, 54B, 54C for each pair of line and load buses 30, 32 associated with a pole of the circuit breaker 20. Additionally, the propeller fans 54A, 54B, 54C are disposed adjacent to the bottom of the housing assembly 12 and structured to move air upwardly from the bottom of the housing assembly 12 and over the load buses 30 and the line buses 32.

While the fan 52 may run continuously, the control assembly 22 may also include a fan control 60 structured to activate the fan 52 when a characteristic of the network protector 10 exceeds a pre-set limit and deactivate the fan 52 when the characteristic drops below a pre-set limit. The characteristic is preferably selected from the following: the current through the circuit breaker 20; the temperature of the bus assembly 31; the temperature of the circuit breaker 20; or the temperature within the housing assembly 12.

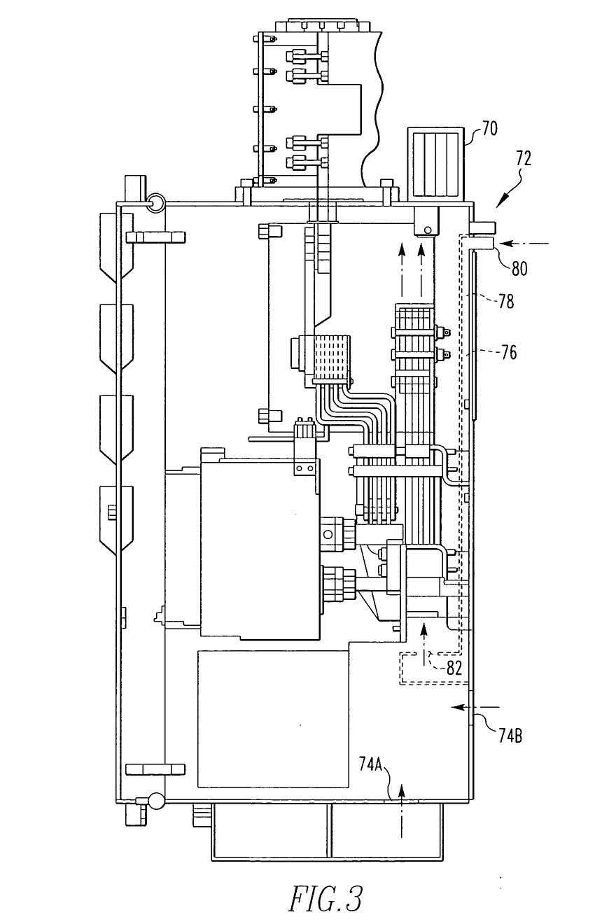

In another embodiment, shown in FIG. 3, the fan 52 is an exhaust fan 70, such as a centrifugal fan, disposed on top of the housing assembly 12. In this embodiment, air is drawn over the load buses 30 and the line buses 32. That is, in addition to the exhaust fan 70, the convection cooling assembly 50 includes an air inlet assembly 72. The air inlet assembly 72 is structured to provide a passage for air to enter the housing assembly 12 at a location adjacent to the bottom of the load buses 30 and the line buses 32. In one embodiment, the air inlet assembly 72 is one or more openings 74A disposed along the bottom of the housing assembly 12, preferably below the load buses 30 and the line buses 32, or one or more openings 74B through the back wall of the housing assembly 12 adjacent to the bottom of the load buses 30 and the line buses 32. However, because network protectors 10 are often disposed in subterranean locations, it is often desirable to not have openings in lower portions of the tank as such openings may let in water. Accordingly, the air inlet assembly 72 may also be a snorkel 76. The snorkel 76 includes a hollow tube 78 having an upper opening 80 disposed outside of the housing assembly 12 adjacent the top of the housing assembly 12 and one or more lower openings 82. The tube 78 extends from the upper opening 80 to a location adjacent the bottom of the load buses 30 and the line buses 32. The lower openings 82 are at the end of the tube 78 opposite the upper opening 80. In operation, the exhaust fan 70 draws air out of the housing assembly 12. As air is withdrawn from the housing assembly 12, the air is replaced by air entering the housing assembly through the inlet assembly 72. Thus, as air is drawn from the inlet assembly 72 to the exhaust fan 70, there is an airflow over the load buses 30 and the line buses 32. As with the propeller fan 54 described above, there may be one exhaust fan 70 for each pole of the circuit breaker 20. However, it is preferred to have a single exhaust fan 70 and allow the inlet assembly 72 to direct air over each pair of load buses 30 and line buses 32. For example, the snorkel 76 may have a cross bar so that the lower opening 82 may be disposed below each pair of load buses 30 and line buses 32.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of invention which is to be given the full breadth of the claims appended and any and all equivalents thereof.

What is claimed is:

1. A network protector comprising:
a housing assembly structured to form an enclosure and having a bus assembly coupled to an interior wall;
a circuit breaker structured to engage said bus assembly within said housing assembly;
a control assembly, said control assembly coupled to said circuit breaker; and
a convection cooling assembly coupled to said housing assembly and structured to move air over said bus assembly.

2. The network protector of claim 1, wherein said convection cooling assembly is at least one fan.

3. The network protector of claim 2, wherein said at least one fan is disposed adjacent to said bus assembly.

4. The network protector of claim 1, wherein
said circuit breaker is a three pole circuit breaker;
said bus assembly includes three pairs of buses, each pair including a line bus and a load bus, associated with each pole of said circuit breaker; and
said at least one fan including three fans, one fan disposed adjacent to each said pair of buses and structured to move a fluid over each bus sub-assembly.

5. The network protector of claim 4, wherein said control assembly includes a control system structured to activate and deactivate said fans.

6. The network protector of claim 5, wherein said control system is structured to activate said fans at a temperature of over between about 135° and 140°, and deactivate said fans at a temperature of below between about 133° and 138°.

7. The network protector of claim 5, wherein said control system is structured to activate said fans at a temperature of over about 139° and deactivate said fans at a temperature of below about 137°.

8. The network protector of claim 5, wherein said control system is structured to detect an increased current through said circuit breaker and is further structured to activate said fans for the duration of the increased current.

9. The network protector of claim 5, wherein said fans are disposed near the bottom of said housing assembly and are structured to move fluid upwardly over said bus assembly.

10. The network protector of claim 2, wherein said at least one fan is a propeller fan.

11. The network protector of claim 1, wherein said cooling assembly includes:
an exhaust fan disposed at the top of the enclosure; and
an inlet assembly structured to provide a passage for air to enter said housing assembly at a location adjacent to the bottom of said bus assembly.

12. The network protector of claim 11, wherein said inlet assembly is one or more openings in said housing assembly.

13. The network protector of claim 11, wherein said inlet assembly is a snorkel.
